(19) United States
(12) Patent Application Publication
(10) Pub. No.: US 2026/0202466 A1
(43) Pub. Date: Jul. 16, 2026

(54) AIR-COOLING DEVICE FOR SEMICONDUCTOR CHIP TESTING

(71) Applicants: HICON CO., LTD., Seongnam-si (KR); Dong Weon HWANG, Seongnam-si Gyeonggi-do (KR); Jae Baek HWANG, Seongnam-si Gyeonggi-do (KR); Logan Jae HWANG, Beverly Hills, CA (US)

(72) Inventors: Dong Weon HWANG, Seongnam-si Gyeonggi-do (KR); Jae Baek HWANG, Seongnam-si Gyeonggi-do (KR); Hyung Suk PARK, Cheonan-si Chungcheongnam-do (KR); Seung Woo RHEE, Seongnam-si Gyeonggi-do (KR)

(21) Appl. No.: 19/450,631

(22) Filed: Jan. 15, 2026

(30) Foreign Application Priority Data
Jan. 15, 2025 (KR) 10-2025-0006316

(51) Int. Cl. G01R 31/28; H05K 7/20

(52) U.S. Cl. CPC G01R 31/2877; H05K 7/20154; H05K 7/20336; H05K 7/20409

(57) ABSTRACT

An air-cooling device for semiconductor chip testing, which has optimized heat transfer efficiency, according to exemplary embodiments of the present invention may include a lower frame, a test module in which a semiconductor chip is accommodated, an upper cover disposed on the lower frame, a cooling module which is coupled to the upper cover and dissipates heat generated by the semiconductor chip, and a pusher module which brings the test module into contact with the cooling module, wherein the cooling module may include a plurality of heat pipes, a plurality of heat dissipation fins through which the heat pipes pass, and a heat dissipation fan which blows air in a direction perpendicular to a staking direction of the heat dissipation fins, and the plurality of heat pipes may be fixedly press-fitted to an upper surface of the pusher module.

### CROSS-REFERENCE TO RELATED APPLICATION

This application claims priority to and the benefit of Korean Patent Application No. 10-2025-0006316, filed on January 15, 2025, the disclosure of which is incorporated herein by reference in its entirety.

### BACKGROUND

### 1. Field of the Invention

The present invention relates to an air-cooling device for semiconductor chip testing, and more specifically, to an air-cooling device for semiconductor chip testing which is capable of effectively dissipating heat generated during a test process of a semiconductor chip, stably coupling a cooling module and a test module, improving heat dissipation performance, and securing both productivity and durability.

### 2. Discussion of Related Art

Modern semiconductor technology requires both high performance and high density, and thus an amount of heat generated by a semiconductor chip is increasing rapidly. Particularly, when excessive heat is generated by the semiconductor chip during a test step, there is a risk that the performance of the normal operation is degraded or serious damage occurs. In order to prevent such problems, a cooling technology for efficiently managing heat generated during a semiconductor chip test process is essential.

First, the conventional air-cooling device has problems that assembly and disassembly are cumbersome and a work time and costs increase due to a complex structure. For example, since a coupling process between a heat pipe and a heat dissipation fin is inefficient, a case in which heat conduction performance is degraded may frequently occurs, which causes a contact failure between a cooling module and a test module and low heat dissipation efficiency. Therefore, excessive heat generated during a test process cannot be properly controlled.

In addition, since a cooling device for semiconductor chip testing is exposed to heat cycles and external impacts during repeating testing, coupling strength and stability between components are very important. However, in the air-cooling device, coupling of components is not tight, and thus there is a problem that durability is low when the air-cooling device is used for long time.

In addition, since coupling and decoupling between the cooling module and the test module are cumbersome, low user convenience becomes an additional problem. When an excessive force is required or manipulation mistakes occur in manipulation, performance and safety of the device may be affected, and thus improvement thereof is needed.

Accordingly, structural improvement to stably and effectively couple a cooling module and a test module through simple manipulation is required, and a new design to improve productivity while maximizing heat dissipation performance is required.

### SUMMARY OF THE INVENTION

The present invention is directed to providing an air-cooling device capable of effectively dissipating heat generated during a semiconductor chip test process.

The present invention is directed to providing an air-cooling device capable of significantly improving a heat dissipation effect by maximizing heat conduction performance through structural optimization of a plurality of heat pipes and heat dissipation fins and applying a forced convection method using a heat dissipation fan.

The present invention is directed to providing an air-cooling device having an effect of improving productivity due to a decrease in assembly time through simplification of a press-fitting process and an increase in coupling force between components using a solder cream during a process of coupling a heat pipe and a pusher module.

The present invention is directed to providing an air-cooling device capable of simplifying manipulation of an upper cover and a pusher module and efficiently pressing an upper cover or lifting a test module with a small force using a pressing lever or lifting lever.

An air-cooling device for semiconductor chip testing, which has optimized heat transfer efficiency, according to exemplary embodiments of the present invention includes a lower frame, a test module in which a semiconductor chip is accommodated, an upper cover disposed on the lower frame, a cooling module which is coupled to the upper cover and dissipates heat generated by the semiconductor chip, and a pusher module which brings the test module into contact with the cooling module, wherein the cooling module includes a plurality of heat pipes, a plurality of heat dissipation fins through which the heat pipes pass, and a heat dissipation fan which blows air in a direction perpendicular to a staking direction of the heat dissipation fins, and the plurality of heat pipes are fixedly press-fitted to an upper surface of the pusher module.

The pusher module may include a pusher plate and a pusher cover, upper heat pipe accommodation grooves and lower heat pipe accommodation grooves, to which the plurality of heat pipes are coupled, may be provided in an upper surface of the pusher plate and a lower surface of the pusher cove, and the heat pipes may be coupled to the pusher module through a press-fitting process in a state in which a solder cream is interposed between the heat pipes and the upper and lower heat pipe accommodation grooves.

Each of the lower heat pipe accommodation grooves may include a first lower accommodation groove which covers both a lower surface and a lower side surface of each of the heat pipes and a second lower accommodation groove which covers an upper side surface of the heat pipe, wherein a diameter of at least a portion of the first lower accommodation groove may be smaller than a diameter of the heat pipe.

The second lower accommodation groove may be formed to have a diameter greater than the diameter of the heat pipe, and the diameter of the second lower accommodation groove may decrease toward the first lower accommodation groove.

The upper heat pipe accommodation groove may include an upper accommodation groove which covers an upper surface of the heat pipe, and the upper accommodation groove may be formed to have a smaller diameter than the first lower accommodation groove and the second lower accommodation groove.

The upper accommodation groove, the first lower accommodation groove, and the second lower accommodation groove may be formed to have the diameters which increase sequentially.

The solder cream may include a metal powder, a flux, and an additive, wherein the metal powder may include one or more selected from the group consisting of tin, silver, copper, bismuth, and antimony.

A particle size of the metal powder may be 1 µm or more and 50 µm or less, and a content of the metal powder may range from 70 wt% to 90 wt% with respect to a total weight of the solder cream.

The flux may include one or more selected from the group consisting of rosin, organic halogen, a solvent, and an activator, and the additive may include one or more selected from the group consisting of an antioxidant, a corrosion inhibitor, an extinction agent, a flame retardant, a thixotropic agent, a film forming agent, and a wax.

The air-cooling device may further include a pressing lever which presses the upper cover in a direction perpendicular to a ground, wherein the pressing lever may be coupled to one side of the upper cover and formed to press the upper cover through uniaxial rotational motion.

At least a portion of the upper cover and at least a portion of the pusher module may be mechanically coupled, and when the upper cover is pressed in the direction perpendicular to the ground by the pressing lever, the pusher module may be controlled to be pressed in the perpendicular direction toward the test module with the upper cover.

The air-cooling device may further include a lifting lever which lifts the pusher module in a direction perpendicular to the ground, wherein the lifting lever may be coupled to an edge region of the test module and lift or lower the test module through uniaxial rotational motion.

The test module may be controlled to be lifted in the direction perpendicular to the ground and in contact with the pusher module when the lifting lever rotates in one direction and controlled to be lowered in the direction perpendicular to the ground and spaced apart from the pusher module when the lifting lever rotates in the other direction opposite to the one direction.

The test module may include a semiconductor chip accommodation part in which the semiconductor chip is accommodated and a test pusher which surrounds an edge of the semiconductor chip accommodation part, wherein the semiconductor chip accommodation part may be disposed in a central portion of the lower frame.

The pusher plate may have an area which is greater than an area of the semiconductor chip accommodation part and smaller than an area of the test pusher.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a front-side perspective view illustrating an air-cooling device for semiconductor chip testing according to exemplary embodiments of the present invention;

FIG. 2 is a cross-sectional view for describing an inner structure of the air-cooling device for semiconductor chip testing according to the exemplary embodiments of the present invention;

FIG. 3 is a bottom-side perspective view illustrating the air-cooling device for semiconductor chip testing according to the exemplary embodiments of the present invention;

FIG. 4 shows side views for describing a driving method of the air-cooling device for semiconductor chip testing according to the exemplary embodiments of the present invention;

FIG. 5 is a cross-sectional view for describing a coupling structure of a cooling module according to the exemplary embodiments of the present invention; and

FIG. 6 is a cross-sectional view for describing a heat pipe accommodation groove according to the exemplary embodiments of the present invention.

### DETAILED DESCRIPTION OF EXEMPLARY EMBODIMENTS

Hereinafter, detailed embodiments of the present invention will be described. The following detailed description is provided to help comprehensive understanding of methods, devices and/or systems described in the present specification. However, these are only examples, and the present invention is not limited thereto.

In descriptions of the invention, when it is determined that detailed descriptions of related well-known technology unnecessarily obscure the gist of the invention, detailed descriptions thereof will be omitted. In addition, some terms described below are defined in consideration of functions in the present invention and meanings may vary depending on a user or operator’s intentions or customs. Therefore, the meanings of terms should be interpreted based on contents throughout the present specification. Terms used in detailed description are provided to only describe embodiments of the present invention and not for purposes of limitation. Unless the context clearly indicates otherwise, the singular forms include the plural forms. The terms “comprise” and “include” in the present specification specify some features, numbers, steps, operations, elements, or some or combinations thereof, but do not preclude the presence or possibility of one or more other features, numbers, steps, operations, elements, or some of combinations thereof in addition to the description.

In addition, in descriptions of components of the embodiments of the present invention, terms such as “first,” “second,” “A,” “B,” “(a),” and “(b)” may be used. The terms are only to distinguish one element from another element, and the essence, order, number, and the like of the elements are not limited thereto by the terms.

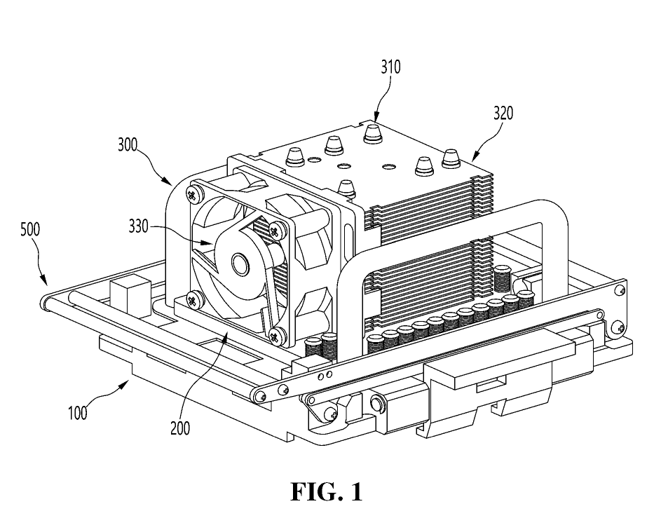

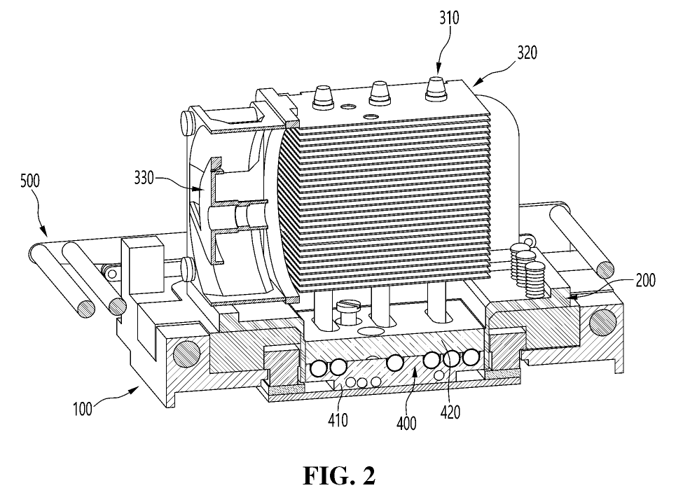

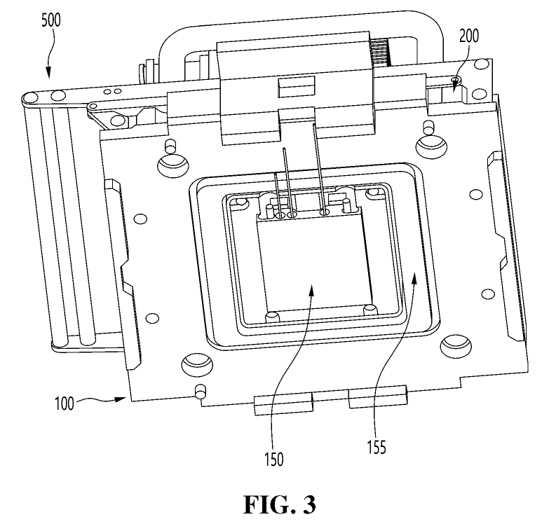

FIG. 1 is a front-side perspective view illustrating an air-cooling device for semiconductor chip testing according to exemplary embodiments of the present invention, FIG. 2 is a cross-sectional view for describing an inner structure of the air-cooling device for semiconductor chip testing according to the exemplary embodiments of the present invention, and FIG. 3 is a bottom-side perspective view illustrating the air-cooling device for semiconductor chip testing according to the exemplary embodiments of the present invention.

Referring to FIGS. 1 to 3, the air-cooling device for semiconductor chip testing, which has optimized heat transfer efficiency, according to the exemplary embodiments of the present invention may include a lower frame 100, a test module 150 and 155 in which a semiconductor chip is accommodated, an upper cover 200 disposed on the lower frame, a cooling module 300 which is coupled to the upper cover to dissipate heat generated by the semiconductor chip, and a pusher module 400 for contacting the test module and the cooling module.

The lower frame 100 is a base element which supports an entire structure of the cooling device of the present invention and serves to stably support main elements such as the cooling module 300, the test module 150 and 155, and the pusher module 400. The lower frame 100 secures the stability of the system by absorbing vibrations or external impacts occurring during a test process and is manufactured of a sturdy material to improve durability. In addition, the lower frame 100 may include a guide element for precise alignment of the cooling module 300 and the pusher module 400.

The test module 150 and 155 is a key component which accommodates the semiconductor chip and is used to test the performance of the chips. The test module 150 and 155 includes a semiconductor chip accommodation part 150 on which the semiconductor chip mounted and a test pusher 155 which surrounds the semiconductor chip accommodation part 150. The semiconductor chip accommodation part 150 is located in a central portion of the lower frame 100 and designed to maintain an exact location of the semiconductor chip. The test pusher 155 guides the semiconductor chip to be stably fixed during the testing and maintains flatness and adhesion to optimize heat dissipation performance during contacting the cooling module 300.

The upper cover 200 serves to stably fix the cooling module 300 and the pusher module 400 onto the lower frame 100. The upper cover 200 is designed such that a user manipulates the upper cover 200 to control coupling of the cooling module 300 and the test module 150 and 155 and may maximize adhesion of the modules through pressing in a direction perpendicular to the ground. Since a pressing lever 500 or lifting lever 500 is coupled to the upper cover 200, the upper cover 200 may be stably manipulated with a small force.

The cooling module 300 may include a plurality of heat pipes 310, a plurality of heat dissipation fins 320 through which the heat pipes pass, and a heat dissipation fan 330 for blowing air in a direction perpendicular to a staking direction of the heat dissipation fins. The plurality of heat pipes 310 may be fixedly press-fitted to an upper surface of the pusher module 400. The heat pipes 310 may be main heat transfer media which transfer heat generated in the semiconductor chip to the heat dissipation fins and may be coupled to the pusher module to efficiently transfer the heat, the heat dissipation fins 320 may be arranged in a stacking stricture to maximize a heat dissipation area so as to quickly dissipate the heat transferred from the heat pipes 310, and the heat dissipation fan 330 may be disposed to accelerate convention heat transfer by forcibly circulating air between the heat dissipation fins 320 and improve heat dissipation performance. The main material of each of the heat pipes 310 may be copper (Cu), and a thermal expansivity of the heat pipe 310 may be about 16.5×10⁻⁶ /ºC.

Meanwhile, the plurality of heat pipes 310 may be press-fitted to the heat dissipation fins 320.

In the exemplary embodiments, the coupling method of the heat dissipation fins 320 may be performed by individually applying a thermal grease method, a thermal pad method, a soldering method, and the like or applying them together as needed.

In one embodiment, a thermal grease may be a metal-based thermal grease, and the metal-based thermal grease may be formed of silver, copper, aluminum, or gold. In another embodiment, a thermal grease may be a ceramic-based thermal grease, and the ceramic-based thermal grease may be formed of aluminum oxide, boron nitride, silicon carbide, or magnesium oxide. In still another embodiment, a thermal grease may be a carbon-based thermal grease, and the carbon-based thermal grease may be formed of diamond particles, carbon nanotubes, or graphene. Alternatively, a thermal grease may be a polymer-based thermal grease, and the polymer-based thermal grease may also be formed of a silicone-oil mixture.

In one embodiment, a thermal pad may be formed of a polymer material, a polymer compound, or another material. The thermal pad formed of the polymer material may be formed of polyurethane, polysiloxane, and the thermal pad formed of the poly compound may be formed of carbon composites, or a metal nano powder mixture (silver, copper nanoparticles). The thermal pad formed of another material may be a ceramic-based thermal pad (aluminum nitride, boron nitride), or a carbon-based thermal pad (graphite, carbon fiber).

In one embodiment, the soldering method may be performed using a soft solder, a lead-free solder, a hard solder, or a flux material, and the soft solder may include a tin-lead (Sn-Pb) alloy, a tin-copper (Sn-Cu) alloy, a tin-silver (Sn-Ag) alloy, a tin-bismuth (Sn-Bi) alloy, or a combination thereof. The lead-free solder may include an Sn-Ag-Cu (SAC alloy), an Sn-Zn (tin-zinc) alloy, an Sn-In (tin-indium) alloy, or a combination thereof, and the hard solder may include a silver-copper alloy, a gold-tin alloy, or a combination thereof. The flux material may include rosin, a no-clean flux, or a combination thereof.

The pusher module 400 may include a pusher plate 410 and a pusher cover 420, and each of the pusher plate 410 and the pusher cover 420 may serve to fix the heat pipe 310 and secure heat transfer performance,

The pusher plate 410 is a structure which supports the heat pipe 310 upward and provides a supporting force such that to the heat pipe 310 is stably fixed in the pusher module 400. The pusher plate 410 may be manufactured of a metal material with high heat conductivity and designed to optimize a contact surface with the heat pipe 310 so as to maximize thermal transfer performance.

The pusher cover 420 is a structure which covers the heat pipe 310 from above and may be designed to stably fix an upper portion and an upper side surface of the heat pipe 310. The pusher cover 420 may prevent shaking or separation of the heat pipe by surrounding the heat pipe 310 with the pusher plate 410.

The pusher plate 410 and the pusher cover 420 may be press-fitted to each other to completely fix the heat pipe 310, a solder cream may be applied during this coupling process, adhesion of the heat pipe 310 and two components 410 and 420 may be improved in the pusher module 400, and heat conduction performance may be optimized.

Meanwhile, the pusher plate 410 and the pusher cover 420 may be sequentially disposed on the semiconductor chip accommodation part 150 of the test module, and when the semiconductor chip is mounted on the semiconductor chip accommodation part 150 and a heating test is performed, the pusher plate 410 may be controlled to be in direct contact with the semiconductor chip mounted in the semiconductor chip accommodation part 150 to perform heat transfer.

In one embodiment, the pusher plate 410 may have an area which is greater than that of the semiconductor chip accommodation part 150 and smaller than that of the test pusher 155.

In the exemplary embodiments, the air-cooling device for semiconductor chip testing may further include the pressing lever 500 for pressing the upper cover 200 in the direction perpendicular to the ground, and the pressing lever 500 may be formed to be coupled to one side of the upper cover 200 to press the upper cover 200 through uniaxial rotational motion.

In one embodiment, at least a portion of the upper cover 200 and at least a portion of the pusher module 400 may be mechanically coupled, and when the upper cover 200 is pressed by the pressing lever 500 in the direction perpendicular to the ground, the pusher module 400 may be controlled to be pressed in the perpendicular direction toward the test module 150 and 155 with the upper cover 200.

In other embodiments, the air-cooling device for semiconductor chip testing may further include the lifting lever 500 for lifting the pusher module 400 in the direction perpendicular to the ground, and the lifting lever 500 may be coupled to edge regions of the test module 150 and 155 and formed to lift or lower the test module 150 and 155 through uniaxial rotational motion.

The test module 150 and 155 may be controlled to be lifted in the direction perpendicular to the ground to come into contact with the pusher module 400 when the lifting lever 500 rotates in one direction and controlled to be lowered in the direction perpendicular to the ground to be spaced apart from the pusher module 400 when the lifting lever 500 rotates in the other direction opposite to the one direction.

The test modules 150 and 155 may include the semiconductor chip accommodation part 150 in which the semiconductor chip is accommodated and the test pusher 155 which surrounds an edge of the semiconductor chip accommodation part, and the semiconductor chip accommodation part 150 may be disposed in the central portion of the lower frame 100.

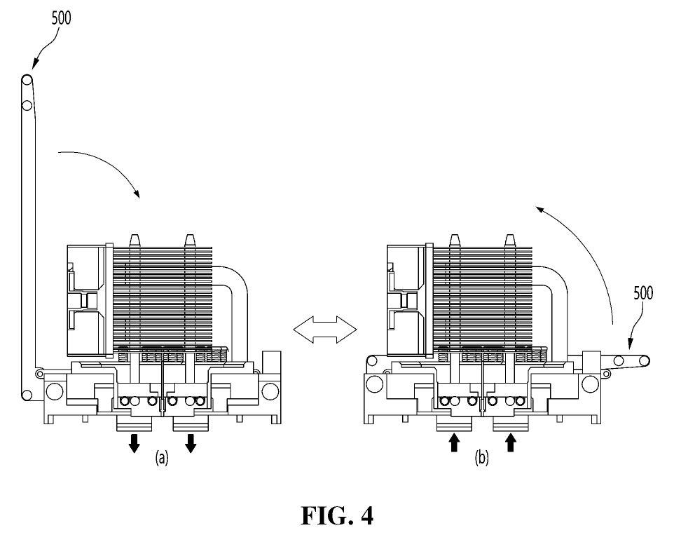

FIG. 4 shows side views for describing a driving method of the air-cooling device for semiconductor chip testing according to the exemplary embodiments of the present invention.

More specifically, FIG. 4A shows a state before the pressing lever 500 or lifting lever 500 is driven, which is a state in which the test module 150 and 155 is not in contact with the pusher module 400, and FIG. 4B shows a state after the pressing lever 500 or lifting lever 500 is driven, which is a state in which the test module 150 and 155 is in contact with the pusher module 400.

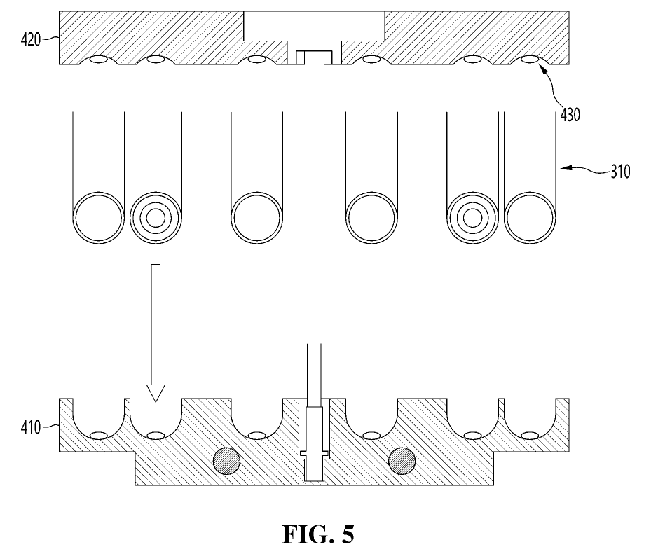

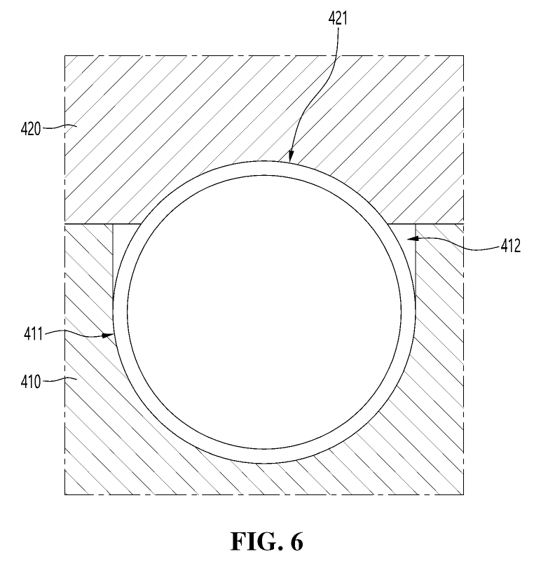

FIG. 5 is a cross-sectional view for describing a coupling structure of the cooling module according to the exemplary embodiments of the present invention, and FIG. 6 is a cross-sectional view for describing a heat pipe accommodation groove according to the exemplary embodiments of the present invention.

Referring to FIGS. 5 and 6, upper and lower heat pipe accommodation grooves 411, 412, and 421 coupled to the plurality of heat pipes 310 may be provided on an upper surface of the pusher plate 410 and a lower surface of the pusher cover 420, and the heat pipes 310 may be coupled to the pusher module 400 through a press-fitting process in a state in which a solder cream 430 is interposed between the upper and lower heat pipe accommodation grooves 411, 412, and 421 and the heat pipes 310.

More specifically, the lower heat pipe accommodation grooves 411 and 412 may include first lower accommodation grooves 411 which cover all lower surfaces and lower side surfaces of the heat pipes 310 and second lower accommodation grooves 412 which cover upper side surfaces of the heat pipes.

Each of the first lower accommodation grooves 411 may be formed to have a diameter smaller than a diameter of the heat pipe 310, and this is for allowing the heat pipe 310 to be closely coupled to the first lower accommodation groove 411. That is, since both the heat pipe 310 and the pusher plate 410 may be formed of metal materials, even when the first lower accommodation groove 411 is formed to have a diameter which is smaller than that of the heat pipe 310 by a predetermined size, the heat pipe 310 or the first lower accommodation groove 411 may be partially compressed or expanded through plastic deformation or elastic deformation, and thus the first lower accommodation groove 411 and the heat pipe 310 may be more closely coupled to each other.

Each of the second lower accommodation grooves 412 may be formed to have a diameter greater than the diameter of the heat pipe 310, and the diameter of the second lower accommodation groove 412 may be formed to be smaller toward the first lower accommodation groove 411. That is, the second lower accommodation groove 412 may be provided with a space for accommodating the heat pipe 310 when a volume of the heat pipe 310 is pushed through the plastic deformation or elastic deformation. In addition, the second lower accommodation groove 412 may be provided to additionally accommodate a portion of the solder cream 430 which fills a gap between the first lower accommodation groove 411 and the heat pipe 310 and is pushed outward.

Each of the upper heat pipe accommodation grooves 421 may include an upper accommodation groove 421 which covers the upper surface of the heat pipe 310, and the upper accommodation groove 421 may be formed to have a smaller diameter than the first lower accommodation groove 411 and the second lower accommodation groove 412. That is, the first lower accommodation groove 411 and the second lower accommodation groove 412 are designed to stably press a half or more portion of the heat pipe 310 while stably supporting the heat pipe upward, and the upper accommodation groove 421 is designed to closely cover the remaining portion of the heat pipe 310 which is smaller than the half portion. In one embodiment, the upper accommodation groove 421, the first lower accommodation groove 411, and the second lower accommodation groove 412 may be formed to have the diameters which increase sequentially.

In the exemplary embodiments, the solder cream 430 may include a metal powder, a flux, and an additive, and the metal powder may include one or more selected from the group consisting of tin, silver, copper, bismuth, and antimony. In this case, a main material of the solder cream 430 may be tin (Sn), and thus, a thermal expansivity of the solder cream 430 may be 21.2×10⁻6 /ºC.

Accordingly, since the heat pipe 310 and the solder cream 430 are formed of different materials, thermal expansivities thereof are different. It is very important to solve a problem of separation and the like which may occur due to the difference in thermal expansivity, and in the present invention, a press-fitting method is applied to the heat pipe 310 and the pusher plate 410, and a bolt coupling method is applied to the heat pipe 310 and the pusher cover 420, and thus the separation problem and the like can be efficiently solved.

In one embodiment, a particle size of the metal powder may be 1 µm or more and 50 µm or less, and a content of the metal powder may range from 70 wt% to 90 wt% with respect to a total weight of the solder cream.

In addition, the flux may include one or more selected from the group consisting of rosin, organic halogen, a solvent, and an activator, and the additive may include one or more selected from the group consisting of an antioxidant, a corrosion inhibitor, an extinction agent, a flame retardant, a thixotropic agent, a film forming agent, and a wax.

Meanwhile, a coupling process of the cooling module related to FIG. 5 will be described below.

First, the solder cream 430 may be applied on the pusher plate 410, the heat pipe 310 may be press-fitted to the pusher plate 410, and then a bolt coupling may be performed such that the solder cream 430 is applied on the pusher cover 420 to cover the upper surface of the heat pipe 310. Accordingly, coupling stability related to the lower surface and a side surface of the heat pipe 310, that is, a lateral separation phenomenon and the like due to thermal expansion and the like, can be supplemented through the press-fitting process, and coupling stability related to the upper surface of the heat pipe 310, that is, a vertical separation phenomenon and the like, can be supplemented through the bolt coupling.

In addition, since a method in which the pusher plate 410 is in direct contact with a heat source is applied instead of a conventional method in which a heat pipe 310 is in direct contact with a heat source, heat transfer efficiency can be optimized by maximizing a thermal contact area, and thus cooling efficiency of the air-cooling device can be significantly improved.

As described above, since the present invention provides the air-cooling device capable of effectively dissipating heat generated during a semiconductor chip test process, a heat dissipation effect can be significantly improved by maximizing heat conduction performance through structural optimization of the plurality of heat pipes 310 and the heat dissipation fins 320 and by applying a forced convention method using the heat dissipation fan 330.

In addition, an effect of increasing productivity due to a decrease in assembly time through simplification of the press-fitting process and an increase in coupling force using the solder cream 430 in a coupling process between the heat pipe 310 and the pusher module 400. In this case, the heat pipes 310 can be stably fixed through an optimized structural design of the upper and lower heat pipe accommodation grooves 411, 412, and 421, and the robustness and durability of the cooling module can be maintained even when the cooling module is used for a long time by optimizing the metal powder and the flux of the solder cream 430.

In addition, in the air-cooling device according to the present invention, since the pressing lever 500 or lifting lever 500 is used, contacting the semiconductor chip and the pusher module 400 can be more efficiently performed by simplifying the manipulation of the upper cover 200 and the pusher module 400 or manipulation of the test module 150 and 155 and the pusher module 400 and efficiently pressing the upper cover 200 or lifting the test module 150 and 155 even with a small force.

Since an air-cooling device capable of effectively dissipating heat generated during a semiconductor chip test process can be provided according to the present invention, a heat dissipation effect can be significantly improved by maximizing heat conduction performance through structural optimization of a plurality of heat pipes and heat dissipation fins and applying a forced convection method using a heat dissipation fan.

In addition, an effect of improving productivity can be obtained due to a decrease in assembly time through simplification of a press-fitting process and an increase in coupling force between components using a solder cream during a process of coupling a heat pipe and a pusher module. In this case, the heat pipe can be stably fixed through an optimized structural design of upper and lower heat pipe accommodation grooves, and the robustness and durability of a cooling module can be maintained even when used for a long time by optimizing a metal powder and a flux of the solder cream.

In addition, contacting a semiconductor chip and a pusher module (400) can be more efficiently performed by simplifying manipulation of an upper cover and a pusher module and efficiently pressing an upper cover or lifting a test module with a small force using a pressing lever and a lifting lever.

However, the concept of the present invention is not necessarily limited thereto, and the device/method/system according to the exemplary embodiments of the present invention may be applied to various products/technical fields other than the above-described product/technical field.

While various embodiments of the preset invention have been described above in detail, it may be understood by those skilled in the art that the embodiments may be variously modified without departing from the scope of the present invention. Therefore, the scope of the present invention is defined not by the described embodiments but by the appended claims, and encompasses equivalents that fall within the scope of the appended claims.

What is claimed is:

1. An air-cooling device for semiconductor chip testing, which has optimized heat transfer efficiency, comprising:
a lower frame;
a test module in which a semiconductor chip is accommodated;
an upper cover disposed on the lower frame;
a cooling module which is coupled to the upper cover and dissipates heat generated by the semiconductor chip; and
a pusher module which brings the test module into contact with the cooling module,
wherein the cooling module includes a plurality of heat pipes, a plurality of heat dissipation fins through which the heat pipes pass, and a heat dissipation fan which blows air in a direction perpendicular to a staking direction of the heat dissipation fins, and
the plurality of heat pipes are fixedly press-fitted to an upper surface of the pusher module.

2. The air-cooling device of claim 1, wherein:
the pusher module includes a pusher plate and a pusher cover;
upper heat pipe accommodation grooves and lower heat pipe accommodation grooves, to which the plurality of heat pipes are coupled, are provided in an upper surface of the pusher plate and a lower surface of the pusher cove; and
the heat pipes are coupled to the pusher module through a press-fitting process in a state in which a solder cream is interposed between the heat pipes and the upper and lower heat pipe accommodation grooves.

3. The air-cooling device of claim 2, wherein each of the lower heat pipe accommodation grooves includes:
a first lower accommodation groove which covers both a lower surface and a lower side surface of each of the heat pipes; and
a second lower accommodation groove which covers an upper side surface of the heat pipe,
wherein a diameter of at least a portion of the first lower accommodation groove is smaller than a diameter of the heat pipe.

4. The air-cooling device of claim 3, wherein:
the second lower accommodation groove is formed to have a diameter greater than the diameter of the heat pipe; and
the diameter of the second lower accommodation groove decreases toward the first lower accommodation groove.

5. The air-cooling device of claim 4, wherein:
the upper heat pipe accommodation groove includes an upper accommodation groove which covers an upper surface of the heat pipe; and
the upper accommodation groove is formed to have a smaller diameter than the first lower accommodation groove and the second lower accommodation groove.

6. The air-cooling device of claim 5, wherein the upper accommodation groove, the first lower accommodation groove, and the second lower accommodation groove are formed to have the diameters which increase sequentially.

7. The air-cooling device of claim 2, wherein the solder cream includes:
a metal powder;
a flux; and
an additive,
wherein the metal powder includes one or more selected from the group consisting of tin, silver, copper, bismuth, and antimony.

8. The air-cooling device of claim 7, wherein:
a particle size of the metal powder is 1 µm or more and 50 µm or less; and
a content of the metal powder ranges from 70 wt% to 90 wt% with respect to a total weight of the solder cream.

9. The air-cooling device of claim 7, wherein:
the flux includes one or more selected from the group consisting of rosin, organic halogen, a solvent, and an activator; and
the additive includes one or more selected from the group consisting of an antioxidant, a corrosion inhibitor, an extinction agent, a flame retardant, a thixotropic agent, a film forming agent, and a wax.

10. The air-cooling device of claim 1, further comprising a pressing lever which presses the upper cover in a direction perpendicular to a ground,
wherein the pressing lever is coupled to one side of the upper cover and formed to press the upper cover through uniaxial rotational motion.

11. The air-cooling device of claim 10, wherein:
at least a portion of the upper cover and at least a portion of the pusher module are mechanically coupled; and
when the upper cover is pressed in the direction perpendicular to the ground by the pressing lever, the pusher module is controlled to be pressed in the perpendicular direction toward the test module with the upper cover.

12. The air-cooling device of claim 1, further comprising a lifting lever which lifts the pusher module in a direction perpendicular to a ground,
wherein the lifting lever is coupled to an edge region of the test module and lifts or lowers the test module through uniaxial rotational motion.

13. The air-cooling device of claim 12, wherein the test module is controlled to be lifted in the direction perpendicular to the ground and in contact with the pusher module when the lifting lever rotates in one direction, and controlled to be lowered in the direction perpendicular to the ground and spaced apart from the pusher module when the lifting lever rotates in the other direction opposite to the one direction.

14. The air-cooling device of claim 2, wherein the test module includes:
a semiconductor chip accommodation part in which the semiconductor chip is accommodated; and
a test pusher which surrounds an edge of the semiconductor chip accommodation part,
wherein the semiconductor chip accommodation part is disposed in a central portion of the lower frame.

15. The air-cooling device of claim 14, wherein the pusher plate has an area which is greater than an area of the semiconductor chip accommodation part and smaller than an area of the test pusher.
